(19) United States
(12) Patent Application Publication
(10) Pub. No.: US 2026/0201547 A1
(43) Pub. Date: Jul. 16, 2026

(54) SUBSTRATE PROCESSING METHOD AND SUBSTRATE PROCESSING APPARATUS

(71) Applicant: Tokyo Electron Limited, Tokyo (JP)

(72) Inventors: Masato ARAKI, Nirasaki City (JP); Atsushi MATSUMOTO, Nirasaki City (JP); Tatsuo HIRASAWA, Nirasaki City (JP)

(21) Appl. No.: 19/440,923

(22) Filed: Jan. 6, 2026

(30) Foreign Application Priority Data
Jan. 10, 2025 (JP) 2025-003879

(51) Int. Cl. C23C 16/04; C23C 16/14; C23C 16/42; C23C 16/455; C23C 16/50; H10D 64/01; H10P 14/43; H10P 50/26

(52) U.S. Cl. CPC C23C 16/045; C23C 16/14; C23C 16/42; C23C 16/4554; C23C 16/45544; C23C 16/50; H10D 64/01125; H10P 14/43; H10P 50/267

(57) ABSTRACT

A substrate processing method includes supplying a first processing gas containing a first metal to a substrate having a recess in which a semiconductor layer containing silicon is exposed on a bottom surface thereof and whose sidewall is formed by an insulator film, and forming a metal silicide film; a plasma processing process of performing at least one of a plasma etching process of supplying a plasma-converted etching gas to the substrate to remove a film of the first metal on the sidewall, or a sidewall processing process of supplying a plasma-converted second processing gas to the substrate to form a metal-containing film of a mixture of the first metal and elements constituting the insulator film, on the sidewall; and supplying a first film-forming gas containing a second metal to the substrate after the plasma processing process and forming a stacked metal film stacked on the metal silicide film.

### CROSS-REFERENCE TO RELATED APPLICATION

This application is based upon and claims the benefit of priority from Japanese Patent Application No. 2025-003879, filed on January 10, 2025, the entire contents of which are incorporated herein by reference.

### TECHNICAL FIELD

The present disclosure relates to a substrate processing method and a substrate processing apparatus.

### BACKGROUND

In the process of manufacturing a semiconductor device, recesses constituting via holes, trenches, and the like are formed in an insulator film formed on a semiconductor wafer (hereinafter referred to as "wafer"), which is a substrate. Then, a process is performed to fill the recesses with a metal film, which is a wiring material, so as to establish an electrical connection with a semiconductor layer containing silicon exposed on the bottom surfaces of the recesses. Before the filling process, the silicon on the bottom surface of the recesses may be converted into a metal silicide, thereby reducing the resistance (contact resistance) at the contact portion between the metal film and the semiconductor layer.

In the related art, after forming a TiSi film on the bottom portion of a recess of a substrate, a Ti film formed on the sidewall of the recess due to the formation of the titanium silicide film is etched and removed by supplying a TiCl₄gas that is not converted into plasma. Furthermore, in a state in which the SiN film forming the sidewall of the recess of the substrate is covered with a SiO₂film, a process is performed by converting gases including a TiCl₄ gas and an H₂ gas into plasma, thereby forming a Ti film on the bottom portion of the recess while preventing the Ti film from being formed on the sidewall of the recess.

### Prior Art Documents

### Patent Documents

Patent Document 1: Japanese patent laid-open publication No. 2002-210713

Patent Document 2: Japanese patent laid-open publication No. 2024-062790

### SUMMARY

According to one embodiment of the present disclosure, there is provided a substrate processing method including: a process of supplying a first processing gas containing a first metal to a substrate having a recess in which a semiconductor layer containing silicon is exposed on a bottom surface of the recess and whose sidewall is formed by an insulator film, and forming a metal silicide film that forms a bottom wall of the recess; a plasma processing process of performing at least one of a plasma etching process of supplying a plasma-converted etching gas to the substrate to remove a film of the first metal on the sidewall of the recess, or a sidewall processing process of supplying a plasma-converted second processing gas to the substrate to form a metal-containing film, which is a mixture of the first metal and elements constituting the insulator film, on the sidewall of the recess; and a film formation process of supplying a first film-forming gas containing a second metal to the substrate after the plasma processing process and forming a stacked metal film stacked on the metal silicide film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional side view of a wafer before undergoing a process according to an embodiment.

FIG. 2A is a vertical sectional side view of a wafer processed according to a first embodiment.

FIG. 2B is a vertical sectional side view of the wafer processed according to the first embodiment.

FIG. 3A is a vertical sectional side view of the wafer processed according to the first embodiment.

FIG. 3B is a vertical sectional side view of the wafer processed according to the first embodiment.

FIG. 4 is a vertical sectional side view of a wafer processed according to a second embodiment.

FIG. 5A is a vertical sectional side view of the wafer processed according to the second embodiment.

FIG. 5B is a vertical sectional side view of the wafer processed according to the second embodiment.

FIG. 6 is a plan view of a substrate processing apparatus that performs the processes according to the first and second embodiments.

FIG. 7 is a vertical sectional side view of a processing module provided in the substrate processing apparatus.

FIG. 8 is a graph showing the results of Evaluation Test 2.

FIG. 9 is a graph showing the results of Evaluation Test 3.

FIG. 10 is a graph showing the results of Evaluation Test 4.

FIG. 11 is a graph showing the results of Evaluation Test 4.

FIG. 12 is a graph showing the results of Evaluation Test 5.

FIG. 13 is a graph showing the results of Evaluation Test 5.

FIG. 14 is a graph showing the results of Evaluation Test 6.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

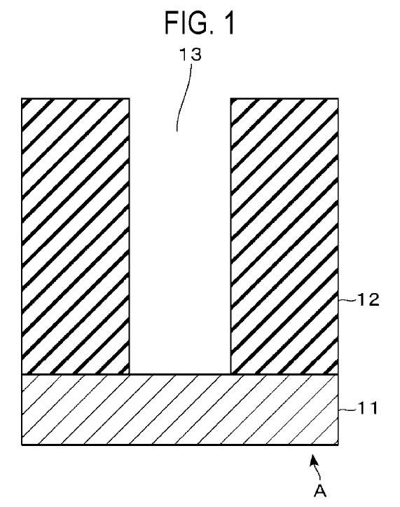

FIG. 1 shows a vertical sectional side view of an example of a wafer A to be processed in first and second embodiments. In the following description on the wafer A, the thickness direction of the wafer A is defined as a vertical direction. The wafer A includes a semiconductor Si (silicon) layer 11, on which a SiN (silicon nitride) film 12 as an insulator film is stacked. An opening is formed in a vertical direction in the SiN film 12. The lower end of the opening reaches the Si layer 11. By providing the SiN film 12 and the opening, a recess 13 that constitutes a trench or hole is formed in the wafer A. The sidewalls of the recess 13 are formed by the SiN film 12 as an insulator film. The bottom wall of the recess 13 is formed by the Si layer 11, i.e., a semiconductor layer containing silicon, and the Si layer 11 is exposed on the surface of the wafer A as the bottom surface of the recess 13.

The processing of the wafer A according to a first embodiment will be described. The respective processes described below are performed by supplying a gas into a processing container in which the wafer A is accommodated in a state in which the interior of the processing container is evacuated to a predetermined vacuum pressure. The respective processes do not necessarily have to be performed in the same processing container, but may be performed in different processing containers. Furthermore, the wafer A is heated to a predetermined temperature in the processing container so that each process can proceed.

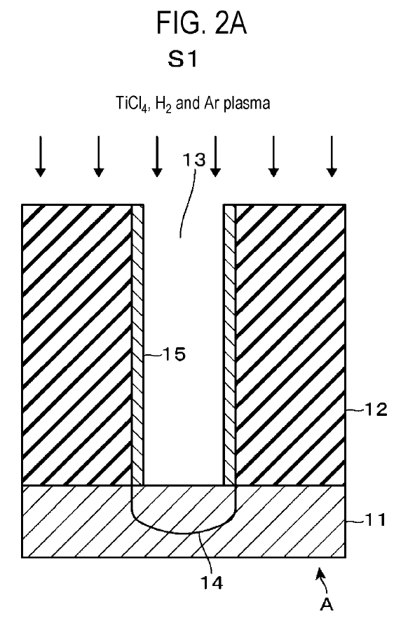

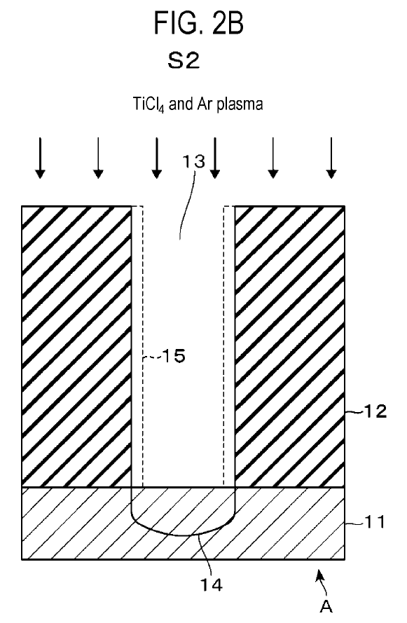

First, a TiCl₄ (titanium tetrachloride) gas, an H₂ (hydrogen) gas, and an Ar (argon) gas are supplied into the processing container accommodating the wafer A shown in FIG. 1, and these gases are converted into plasma to perform plasma CVD (FIG. 2A, step S1). The TiCl₄ gas is a first processing gas for forming a metal silicide film. The H₂ gas is a gas for reacting with and removing chlorine constituting TiCl₄, and the Ar gas is a gas for forming plasma. By supplying these gases, the portion of the Si layer 11 exposed at the bottom surface of the recess 13 reacts with Ti, which is a first metal contained in TiCl₄, to form a TiSi (titanium silicide) film 14, which is a metal silicide film, on the bottom wall of the recess 13. Meanwhile, a Ti (titanium) film 15 is formed on the sidewall of the recess 13.

Next, a TiCl₄ gas and an Ar gas are supplied into the processing container, and these gases are converted into plasma to perform plasma etching (FIG. 2B, step S2). The Ti film 15 on the sidewall of the recess 13 is etched by the action of activated chlorine species, such as chlorine and ions, which are mainly generated from TiCl₄. The TiCl₄ gas and the Ar gas used in step S2 are etching gases for plasma etching. Therefore, the gas for plasma etching and the gas for metal silicide formation include TiCl₄ gas.

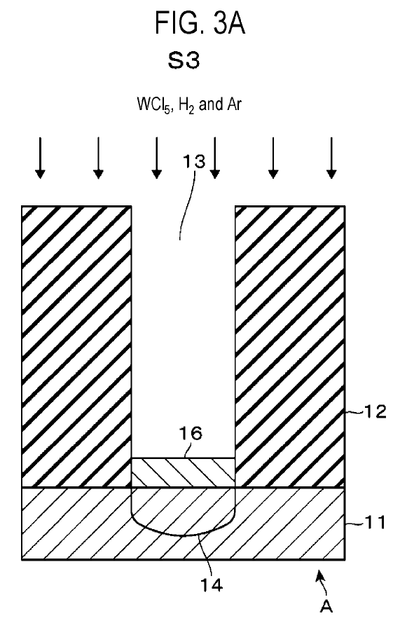

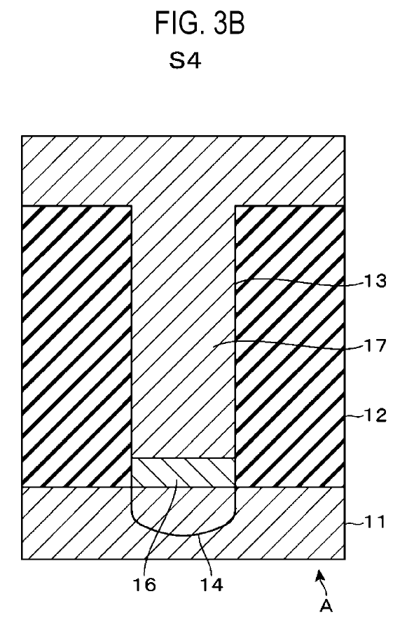

Then, a WCl₅ (tungsten pentachloride) gas, an Ar gas, and a H₂ gas are supplied into the processing container to perform CVD, thereby forming a W (tungsten) film 16 in the recess 13 so as to be stacked on the TiSi film 14 (FIG. 3A, step S3). The WCl₅ gas is a first film-forming gas for performing film formation, the H₂ gas is a gas for reacting with and removing chlorine constituting WCl₅, the Ar gas is a carrier gas, and W contained in the WCl₅ is a second metal. As shown in the evaluation tests described later, when the gases including the WCl₅ gas are supplied to the substrate in this manner, a W film is formed on the Ti film, while formation of a W film on the SiN film is suppressed. Since the Ti film 15 is etched in step S2 as described above, the process of step S3 suppresses formation of the W film 16 on the sidewall of the recess 13, which is the SiN film 12, and selectively forms the W film 16 on the bottom wall of the recess 13.

The supply of the WCl₅ gas, the Ar gas, and the H gas is stopped before the W film 16, which is a stacked metal film to be stacked on the TiSi film 14, fills the recess 13 (i.e., before the upper surface of the W film 16 whose thickness increases within the recess 13 reaches the upper end of the recess 13), and step S3 is ended. Therefore, the W film 16 is formed in the recess 13 as a thin film having a relatively small thickness.

Thereafter, a gas including a WF₆ (tungsten hexafluoride) gas is supplied as a second film-forming gas into the processing container, and a W film as a metal film is filled in the recess 13 as shown in FIG. 3B (step S4). Like step S3, step S4 is a step for forming a W film, but the compound constituting the gas used for film formation is different from that of step S3. For convenience of illustration, the W film formed by the WF₆ gas is shown as a W film 17 to distinguish it from the W film 16 formed by the WCl₅ gas. Together with the W film 16, the W film 17 forms the wirings of the semiconductor device manufactured from the wafer A. The portion of the W film 17 formed above the recess 13 is later removed by CMP.

The reason why the W film 16 is formed in step S3 before the W film 17 is formed in step S4 will be explained. From the viewpoint of increasing the film formation efficiency, it is preferable to use the WF₆ gas rather than the WCl₅ gas to fill the recess 13 with the W film 17. Therefore, the WF₆ gas is used in the above-mentioned step S4, which performs the filling. However, fluorine that constitutes WF₆ has a relatively high etching effect on the TiSi film 14. For this reason, the W film 16 is formed using the WCl₅ gas in step S3. The W film 16 covers the TiSi film 14 and protects the TiSi film 14 from being etched during the filling of the W film 17.

When the wafer A is exposed to the ambient air between the formation of the TiSi film 14 and the filling of the W film 17 into the recess 13, the W film 16 also serves to prevent the surface of the TiSi film 14 from being oxidized by the ambient air and to prevent the contact resistance from increasing. An example of such a case in which the wafer A is exposed to the ambient air includes a case where the wafer A is moved from an apparatus for forming the TiSi film 14 to an apparatus for filling the W film 17 through the ambient air atmosphere.

As described above, according to the first embodiment, the Ti film 15 on the sidewall of the recess 13 is etched. Therefore, compared to a case where the Ti film 15 is not etched, the volume of the W film 17 filled in the recess 13 is larger. Ti has a higher electrical resistance than W. Therefore, in the first embodiment, it is possible to suppress an increase in the resistance of the wiring formed in the recess 13. Furthermore, by etching the Ti film 15 on the sidewall of the recess 13, the formation of the W film 16 on the sidewall of the recess 13 in step S3 is suppressed. By suppressing the formation of the W film 16 on the sidewall in this manner, the W film 17 is prevented from growing in the horizontal direction from the W film 16 on the sidewall when step S4 is performed. If the W film 17 were to grow in the horizontal direction, the opening of the recess 13 would be blocked before the W film 17 is filled in the recess 13, potentially resulting in the formation of air gaps called voids in the W film 17. As described above, according to the first embodiment, the formation of the W film 16 on the sidewall of the recess 13 is suppressed, thereby preventing defects in the filling of the W film 17 into the recess 13. That is, defects in the formation of each of the W films 16 and 17 are suppressed.

Furthermore, in the first embodiment, the Ti film 15 is etched by converting the TiCl₄ gas into plasma. As will be shown in the evaluation tests described later, the etching of the Ti film 15 can be completed more quickly than when etching is performed without converting the TiCl₄ gas into plasma. Therefore, according to the first embodiment, it is possible to increase the throughput of an apparatus or system that performs processes from the formation of the TiSi film 14 to the filling of the W film 17 into the recess 13.

### Second Embodiment

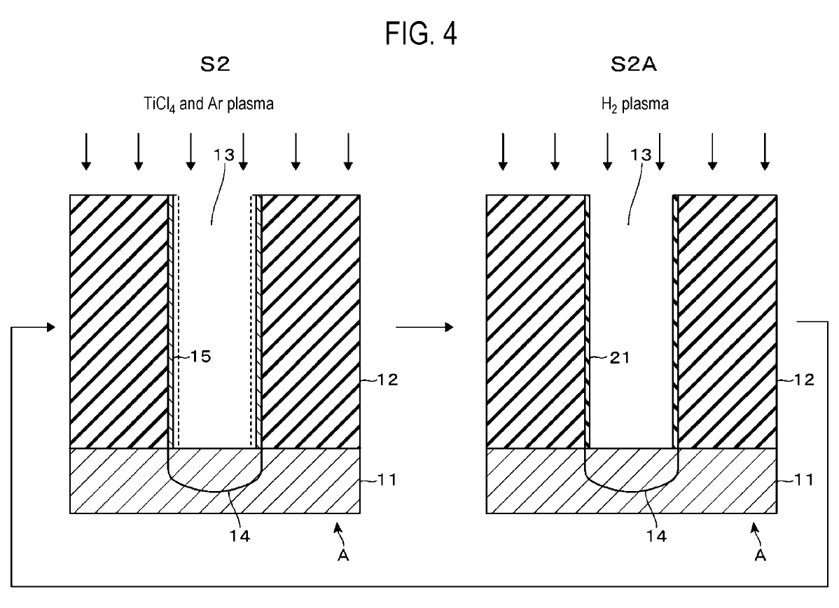

The process of a second embodiment will be described, focusing on the differences from the first embodiment. First, the wafer A shown in FIG. 1 is subjected to the process of step S1, thereby forming a TiSi film 14 on the bottom wall of the recess 13 and a Ti film 15 on the sidewall thereof. Then, step S2 is performed, thereby etching and thinning the Ti film 15 (left side of FIG. 4). Thereafter, a H₂ gas, which is the second process gas, is supplied into the processing container in which the wafer A is accommodated, and the H₂ gas is converted into plasma (right side of FIG. 4, step 2A). Under the action of the converted H₂gas, Ti which is an element constituting the Ti film 15 is mixed with Si and N which are elements constituting the sidewall of the recess 13, thereby forming a TiSiN (titanium silicide nitride) film 21, which is a metal nitride silicide film, on the surface layer portion of the sidewall of the recess 13.

After the process of step S2A is performed, the process of step S2 is performed again, and then the process of step S2A is performed again. That is, step S2 and step S2A, which is performed after step S2, constitute one cycle, and this cycle is performed repeatedly. By repeating the cycle, the etching of the Ti film 15 and the formation of the TiSiN film 21 progress.

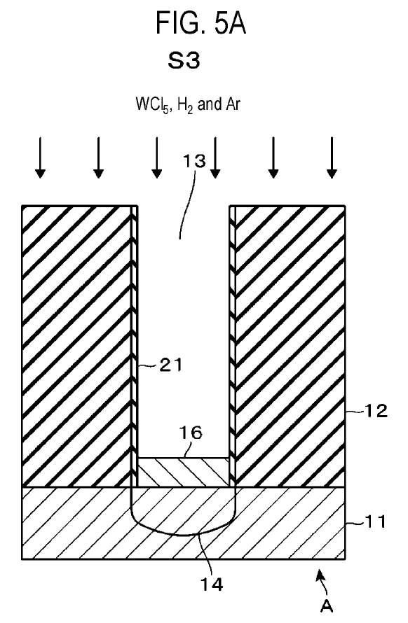

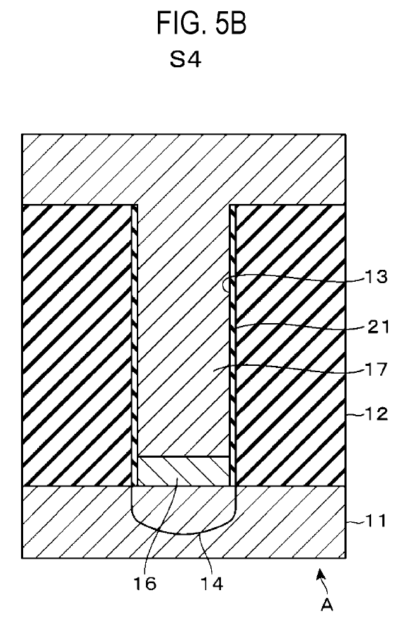

After this cycle is performed a predetermined number of times, step S3 is performed, as in the first embodiment. As will be shown in the evaluation tests described later, the W film 16 is less likely to be formed on the TiSiN film 21 than on the Ti film 15. That is, it can be said that step S2A is a process for modifying the sidewall of the recess 13. By modifying the sidewall and etching the Ti film 15 in this way, the W film 16 is selectively formed on the bottom portion of the recess 13 in this second embodiment as in the first embodiment (FIG. 5A). Then, the process of step S4 is performed, and the W film 17 is filled into the recess 13 (FIG. 5B).

The second embodiment described above is preferable because it can more reliably suppress the formation of the W film 16 on the sidewall of the recess 13. In the second embodiment, each of steps S2 and S2A may be performed only once without being repeated. That is, the processes may be performed in the order of steps S1, S2, S2A, S3, and S4.

The order of steps S2 and S2A may be a reverse of the example described with reference to FIG. 4. That is, steps S1, S2A, S2, S3, and S4 may be performed in the named order. Even when S2A is performed first among steps S2 and S2A, S2A and S2 may be treated as one cycle, and the cycle may be repeated. That is, after performing step S1, steps S2A, S2, S2A, S2, and the like may be performed in the named order, thereby repeating the modification of the sidewall of the recess 13 and the etching of the Ti film 15 on the sidewall. However, if the thickness of the Ti film 15 is too large when performing step S2A, the H₂ gas plasma may not sufficiently act on the SiN film 12, or Ti, Si, and N may not be sufficiently mixed in the TiSiN film 21, potentially reducing the sidewall modification effect. To prevent this, as for steps S2 and S2A, it is preferable to perform step S2 first and then perform step S2A.

### Configuration Example of Substrate Processing Apparatus

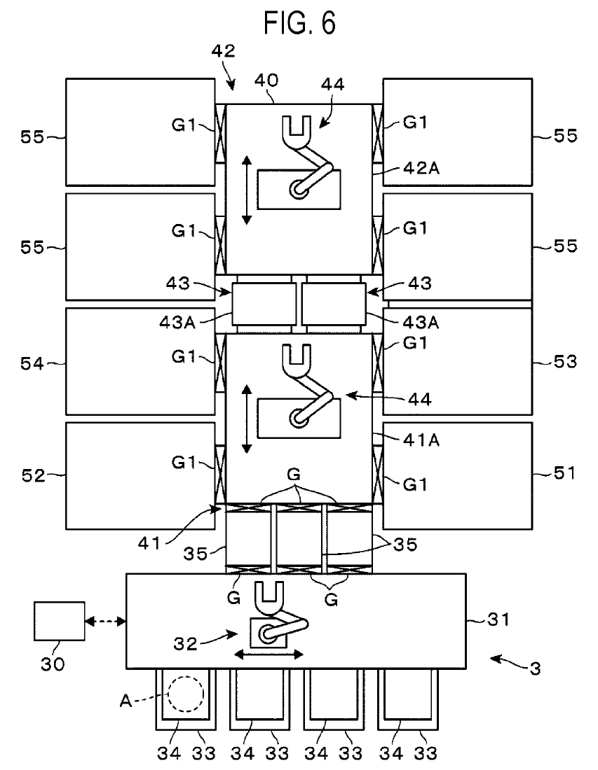

Next, a configuration example of the substrate processing apparatus 3 capable of performing steps S1 to S3 of the first and second embodiments described above will be described with reference to the plan view of FIG. 6. The substrate processing apparatus 3 includes a loader module 31, a load lock module 35, a first vacuum transfer module 41, a second vacuum transfer module 42, a connection module 43, and processing modules 51 and 52. The processing module 51 performs the processes of steps S1, S2, and S2A, and the processing module 52 performs the process of step S3. In the following description, the first vacuum transfer module 41 and the second vacuum transfer module 42 may be collectively referred to as vacuum transfer modules 41 and 42.

The loader module 31, the load lock module 35, the first vacuum transfer module 41, the connection module 43, and the second vacuum transfer module 42 are arranged in a straight line in the horizontal direction in the named order. In the following description of the substrate processing apparatus 3, the side where the loader module 31 is located will be referred to as the front side, and the side where the second vacuum transfer module 42 is located will be referred to as the rear side. The load lock module 35 will be referred to as the LLM 35 hereinafter.

The loader module 31 includes a housing whose interior is kept at the atmospheric pressure, a transfer mechanism 32 for wafers A provided within the housing, and load ports 33. In this example, four load ports 33 are provided side by side on the front side of the housing. A transfer container 34 for storing wafers A, known as a FOUP (Front Opening Unified Pod), is placed on each load port 33. The transfer mechanism 32 is formed, for example, by a multi-joint arm that can move left and right, and is capable of transferring the wafers A between the transfer container 34 on each load port 33 and each load lock module 35.

In this example, three LLMs 35 are provided side by side. Each LLM 35 has a housing, which is connected to the loader module 31 and the first vacuum transfer module 41 via gate valves G provided at the front and rear sides of the housing, respectively. When the gate valves G at the front and rear sides of the housing are closed, the pressure inside the housing can be freely changed between an atmospheric pressure and a vacuum pressure. A stage (not shown) on which the wafer A is placed is provided within the housing of each LLM 35. The stage is configured to be able to transfer the wafer A to and from the transfer mechanism 32 and the transfer mechanism 44 (described later), which access the LLMs 35.

The first vacuum transfer module 41 and the second vacuum transfer module 42 are configured similarly to each other and include housings 41A and 42A, respectively. The interiors of the housings 41A and 42A are evacuated by exhaust mechanisms (not shown). In this example, two connection modules 43 are provided side by side. The connection module 43 includes a housing 43A, which is connected to the housings 41A and 42A of the vacuum transfer modules 41 and 42.

By performing evacuation with the exhaust mechanism, the inside of the housing 43A of the connection module 43 is also set to a vacuum atmosphere which is the same pressure as the pressure inside the housings 41A and 42A. A stage (not shown) on which the wafer A is placed is provided inside the housing 43A, where the stage is configured to be able to deliver the wafer A to and from a transfer mechanism 44 (described later). Hereinafter, the insides of the housings 41A, 42A, and 43A, which are set to a vacuum atmosphere, will be collectively referred to as a vacuum transfer path 40. An inert gas supply mechanism that supplies an inert gas to the vacuum transfer path 40 is provided, and the pressure in the vacuum transfer path 40 is adjusted to a desired vacuum pressure by supplying and discharging the inert gas.

Two processing modules are arranged side by side on the left and right sides of the housing 41A of the first vacuum transfer module 41 and the housing 42A of the second vacuum transfer module 42. Each processing module is connected to the housing 41A or 42A via a gate valve G1. In this example, the processing module 51 is connected to the housing 41A, and the processing module 52 is connected to the housing 42A.

A transfer mechanism 44 is provided in each of the housings 41A and 42A, and each transfer mechanism 44 is configured, for example, by a multi-joint arm that can move back and forth. The transfer mechanism 44 in the housing 41A delivers wafers A between the LLMs 35, the connection module 43, and each processing module connected to the housing 41A via the gate valve G1. The transfer mechanism 44 in the housing 42A delivers wafers A between the connection module 43 and each processing module connected to the housing 42A via the gate valve G1. The gate valves G and G1 are closed except when necessary to deliver wafers A between the modules, thereby separating the atmospheres between the modules. Each stage of the load lock module 35 and the connection module 43 is provided with, for example, pins that can protrude from and retract into the stage to allow delivery of wafers A to and from the transfer mechanism.

The substrate processing apparatus 3 includes a controller 30, which is a computer. The controller 30 includes a program. The program contains instructions (steps) for use in processing wafers A in the processing modules 51 and 52 and transferring wafers A in the substrate processing apparatus 3. The program is stored on a storage medium, such as a compact disc, a hard disk, or a DVD, and is installed in the controller 30. The controller 30 outputs control signals to the respective parts of the substrate processing apparatus 3 using the program to control the operations of the respective parts. Specifically, the controller 30 controls the operations of the processing modules 51 and 52, the opening and closing of the gate valves G and G1, the operations of the transfer mechanisms 32 and 44, the operation of the exhaust mechanism, the operation of the inert gas supply mechanism, and the pressure changes within the LLMs 35. The control of the operations of the processing modules 51 and 52 includes control of the temperature of the wafer A on the stage 66 by supplying power to a heater 67 (described later), control of the switching between supplying and stopping the supply of each gas into the processing container 61 by opening and closing valves V, and control of the switching of the on/off operations of radio-frequency power supplies 69 and 75.

### Configuration of Processing Module 51

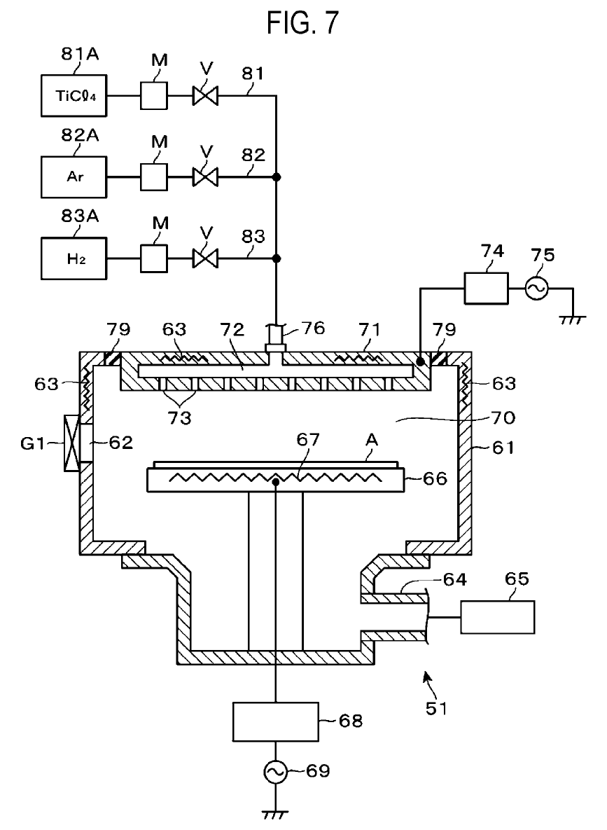

The processing module 51 will be described with reference to the vertical sectional side view of FIG. 7. The processing module 51 is a capacitively-coupled plasma processing apparatus equipped with a metal processing container 61 which is grounded. A transfer port 62 for a wafer A is provided in the sidewall of the processing container 61, and the transfer port 62 is opened and closed by the gate valve G1 described above. A heater 63 for regulating the temperature inside the processing container 61 is embedded in the sidewall of the processing container 61 and a shower head 71 (described below) that forms a ceiling wall of the processing container 61. One end of an exhaust path 64 is opened at the bottom of the processing container 61, and the other end of the exhaust path 64 is connected to an exhaust mechanism 65 including a valve and a vacuum pump. The exhaust mechanism 65 evacuates the processing container 61 to create a vacuum atmosphere of a desired pressure in the processing container 61.

A stage 66 is provided within the processing container 61, and the wafer A is horizontally placed on the stage 66. Above the stage 66 is a processing space 70 to which gases are supplied from a shower head 71, which will be described later. A heater 67 is embedded in the stage 66 as a heating mechanism, and the heater 67 heats the placed wafer A to a preset processing temperature. The stage 66 also functions as a lower electrode, and is connected to a radio-frequency power supply 69 via a matching box 68, which supplies radio-frequency power for bias application (for attracting ions of plasma). Although not shown, three pins that can be raised from and lowered to the upper surface of the stage 66by an elevating mechanism are provided. The wafer A can be delivered between the upper surface of the stage 66 and the transfer mechanism 44 via the pins.

A shower head 71 is provided on the ceiling wall of the processing container 61 and is attached to the processing container 61 via an insulating member 79. The shower head 71 includes a gas diffusion space 72 and a number of discharge holes 73 opened downward to discharge gases supplied from the diffusion space 72 toward the processing space 70. The shower head 71 is configured as an upper electrode, and is connected to a radio-frequency power supply 75 via a matching box 74, which supplies radio-frequency power for plasma generation.

Radio-frequency power of a predetermined frequency is supplied from the radio-frequency power supply 75 to the shower head 71, whereby the gas supplied from the shower head 71 to the processing space 70 is converted into plasma. While the radio-frequency power is supplied from the radio-frequency power supply 75, the radio-frequency power is supplied from the radio-frequency power supply 69 to the stage 66, thereby drawing ions that constitute the plasma into the stage 66. The frequency of the radio-frequency power supplied from the radio-frequency power supply 75 to the shower head 71 is higher than the frequency of the radio-frequency power supplied from the radio-frequency power supply 69 to the stage 66.

The downstream end of a gas flow path 76 is connected to the diffusion space 72 of the shower head 71. The upstream side of the gas flow path 76 branches to form gas flow paths 81 to 83. The upstream end of the gas flow path 81 is connected to a TiCl₄ gas supply source 81A, the upstream end of the gas flow path 82 is connected to an Ar (argon) gas supply source 82A, and the upstream end of the gas flow path 83 is connected to an H₂ (hydrogen) gas supply source 83A. In each of the gas flow paths 81 to 83, a valve V and a flow rate controller M, which is configured by a mass flow controller or the like, are arranged in order toward the upstream side. The opening and closing the valve V switches between supplying and stopping each gas from each of the gas supply sources 81A to 83A to the processing space 70 via the shower head 71. The flow rate controller M adjusts the flow rate of each gas supplied to the processing space 70 to a preset flow rate.

### Configuration of Another Processing Module

The processing module 52 has a configuration generally similar to the configuration of the processing module 51, except that a WCl₅ gas supply source is provided instead of the TiCl₄ gas supply source 81A. A WCl₅ gas is supplied from the WCl₅ gas supply source to the processing space 70 via a flow path equipped with a valve V and a flow rate controller M, whereby a wafer A is processed. Furthermore, the processing module 52 differs from the processing module 51 in that it does not perform plasma processing on a wafer A and therefore does not include the radio-frequency power supplies 75 and 69.

The TiCl₄ gas supply source 81A in the processing module 51, and the valve V and the flow rate controller M provided in the gas flow path 81 constitute a first processing gas supply for forming a TiSi film 14. Furthermore, the TiCl₄ gas supply source 81A, the Ar gas supply source 82A, the valves V and the flow rate controllers M provided in the gas flow paths 81 and 82, and the radio-frequency power supply 75 for converting a gas into plasma constitute a plasma etching gas supply for supplying a plasma-converted etching gas for etching the Ti film 15. The H₂ gas supply source 83A, the valve V and the flow rate controller M provided in the gas flow path 83, and the radio-frequency power supply 75 constitute a second processing gas supply for modifying the sidewall of the recess 13. Each of the second processing gas supply and the plasma etching gas supply corresponds to a plasma processing part. The WCl₅ gas supply source in the processing module 52, and the valve V and the flow rate controller M provided in the WCl₅ gas flow path constitute a first film-forming gas supply. The plasma processing process of step S2 corresponds to a plasma etching process, the plasma processing process of step S2A corresponds to a sidewall processing process, and the processing step of step S3 corresponds to a film-forming step for forming a stacked metal film.

### Operation of Substrate Processing Apparatus 3

The operation of the substrate processing apparatus 3 will be described assuming that a wafer A is subjected to the processing according to the second embodiment. The wafer A is unloaded from the transfer container 34 and transferred to the loader module 31, the LLM 35, and the vacuum transfer path 40 in the named order. Thereafter, the wafer A is placed on the stage 66 of the processing module 51 and heated to a predetermined processing temperature, e.g., 450 degrees C. A TiCl₄ gas, an H₂ gas, and an Ar gas are supplied to the processing space 70 of the processing module 51, and the pressure in the processing space 70 is set to, e.g., 5Torr (6.67×10² Pa). Meanwhile, radio-frequency power is supplied from the radio-frequency power supplies 75 and 69 to the shower head 71 and the stage 66, respectively, to generate plasma from the gases and to attract ions from the plasma to the wafer A. As a result, step S1 described in FIG. 2A is performed on the wafer A described in FIG. 1, thereby forming a TiSi film 14 on the bottom wall of the recess 13.

Thereafter, the supply of the H₂ gas to the processing space 70 is stopped. While the pressure in the processing space 70 is maintained at, for example, 5 Torr, the supply of the TiCl₄ gas and the Ar gas and the supply of radio-frequency power from the radio-frequency power supplies 75 and 69 are continued, and step S2 is performed instead of step S1. That is, the Ti film 15 formed on the sidewall of the recess 13 during the processing of step S1 is etched. Subsequently, the pressure in the processing space 70 becomes, for example, 9 Torr (1.2×10³ Pa), and the gas supplied to the processing space 70 is changed from the TiCl₄ gas and the Ar gas to the H₂ gas, thereby performing step S2A to form a TiSiN film 21 on the sidewall of the recess 13.

Thereafter, the pressure in the processing space 70 and the gas supplied to the processing space 70 are changed, thereby repeating the cycle consisting of steps S2 and S2A described with reference to FIG. 4. After this cycle has been repeated a predetermined number of times, the supply of each gas to the processing space 70 and the supply of radio-frequency power from the radio-frequency power supplies 75 and 69 are stopped, and the wafer A is transferred from the processing module 51 to the processing module 52 via the vacuum transfer path 40. While setting the pressure in the processing space 70 of the processing module 52 to, for example, 50 Torr (6.67×10³ Pa) and heating the wafer A to, for example, 450 degrees C, a WCl₅ gas, an H₂ gas, and an Ar gas are supplied to the processing space 70, and the process of step S3 shown in FIG. 5A is performed, thereby forming a W film 16 stacked on the TiSi film 14. Thereafter, the supply of these gases to the processing space 70 is stopped, and the wafer A is transferred through the vacuum transfer path 40, the LLM 35, and the loader module 31 in the named order, and then returned to the transfer container 34.

The transfer container 34 is transferred in the ambient air atmosphere by a transfer mechanism for the transfer container to a substrate processing apparatus (referred to as a substrate processing apparatus 3A for the sake of convenience) other than the substrate processing apparatus 3, and step S4 is performed by the substrate processing apparatus 3A. That is, by supplying a WF₆ gas, a W film 17 is filled into the recess 13 as shown in FIG. 5B. The substrate processing apparatus 3A has the same configuration as the substrate processing apparatus 3, except that it includes, for example, a processing module (referred to as a processing module 53 for the sake of convenience) for performing step S4. The substrate processing apparatuses 3 and 3A constitute a substrate processing system for processing a wafer A. The processing module 53 has the same configuration as the processing modules 51 and 52, except that it includes, for example, a gas supply source capable of supplying a WF₆ gas to a wafer A.

When processing the wafer A in the first embodiment using the substrate processing apparatus 3, the processing and transfer of the wafer A may be performed in the same manner as described above, except that only step S2 of steps S2 and S2A is performed in the processing module 51. The configuration of the substrate processing apparatus 3 may be modified as appropriate. For example, a processing module for removing a native oxide film formed on the surface of the Si layer 11 before the process of step S1 may be provided in place of some of the plurality of processing modules 51 or some of the plurality of processing modules 52. Furthermore, the plurality of processing modules connected to the vacuum transfer path 40 of the substrate processing apparatus 3 may include the processing module 53 for filling the W film 17 described above. By providing such a processing module 53, the series of processes of steps S1 to S4 may be performed within the substrate processing apparatus 3.

Steps S1, S2, and S2A do not necessarily have to be performed in the same processing module 51, but may be performed in separate processing modules. However, since the TiCl₄gas and the Ar gas are commonly used in the processes of steps S1 and S2, and the H₂ gas is commonly used in the processes of steps S2 and S2A, it is preferable to perform steps S1, S2, and S2A in the same processing module 51 from the viewpoint of preventing an increase in manufacturing costs due to providing mechanisms for supplying the same type of gases for the respective processing modules. It is also preferable to perform steps S1, S2, and S2A in the same processing module 51 from the viewpoint of reducing the time required to transfer the wafer A and achieving high throughput in the substrate processing apparatus 3.

Incidentally, in the second embodiment, both step S2 of etching the Ti film 15 and step S2A of forming the TiSiN film 15 are performed, but only step S2A of steps S2 and S2A may be performed. Therefore, etching of the Ti film 15 is not necessarily performed between the formation of the TiSi film 14 in step S1 and the formation of the W film 16 in step S3. However, as described above, if the thickness of the Ti film 15 is large, the effect of modifying the sidewall of the recess 13 is reduced. Therefore, it is preferable to perform both steps S2 and S2A.

Furthermore, when the formation of the TiSiN film 21 in step S2A and the etching of the Ti film 15 are performed between step S1 and step S3, the etching of the Ti film 15 is not limited to the plasma processing shown in the second embodiment. That is, the etching of the Ti film 15 may be performed by supplying respective gases including an etching gas without generating plasma. Specifically, for example, the etching of the Ti film 15 may be performed by supplying a TiCl₄ gas and an H₂ gas to the wafer A without generating plasma.

If a process of supplying the TiCl₄ gas and the H₂ gas that are not converted into plasma is designated as step S2B, step S2B may be performed instead of step S2 in the process of performing both steps S2 and S2A described above as the second embodiment. That is, either step S2A or S2B may be performed first. The process may be performed by repeating a cycle in which steps S2A and S2B are alternately performed, or steps S2A and S2B may be performed once without repeating the cycle. However, as described above, from the viewpoint of throughput, performing step S2, which is plasma processing, is preferable to performing step S2B, which is non-plasma processing.

The modification process for the sidewall of the recess 13 in step S2A is not limited to using the plasma of the H₂ gas. Plasma of an inert gas, such as an Ar gas or a N₂ (nitrogen) gas, may also be used. However, if a gas with a relatively large molecular weight, such as an Ar gas or an N₂ gas, is converted into plasma and supplied to the wafer A, the etching effect on the TiSi film 14 may be relatively large. Furthermore, because of the large molecular weight, the plasma does not easily penetrate into the sidewall of the recess 13, and the modification effect may be relatively small. Therefore, in order to suppress etching of the TiSi film 14 and obtain a high modification effect, it is preferable to perform step S2A using the plasma of the H₂ gas, which has a relatively small molecular weight.

Furthermore, since the Ti film 15 is etched in step S2 by the action of chlorine and activated chlorine species as described above, a metal chloride gas other than the TiCl₄ gas may be supplied to the wafer A, and the gas may be converted into plasma to etch the Ti film 15. Specifically, a gas such as ZrCl4, WCl5, TaCl5, MoCl5 or the like may be supplied to the wafer A and converted into plasma to etch the Ti film 15. Therefore, the etching gas is not limited to the TiCl₄ gas. However, it is preferable to perform step S2 using the TiCl₄ gas, which is the gas used to form the TiSi film 14 in step S1, as the etching gas, from the viewpoint of preventing the apparatus configuration from becoming complicated and the manufacturing costs from increasing. For the same reason, the etching gas in step 2B, which is the non-plasma etching process described above, is not limited to the TiCl₄ gas, but the TiCl₄ gas is preferably used as the etching gas.

Although steps S2 and S2A are described as being performed after the Ti film 15 is formed on the entire sidewall of the recess 13 in step S1, the Ti film 15 is not limited to covering the entire sidewall and may be provided in a scattered-manner on the sidewall. Furthermore, the silicon layer 11 on which the TiSi film 14 is formed in step S1 may be the wafer A itself or a film formed on the wafer A. The formation of the TiSi film 14 in step S1 is not limited to plasma processing and may be performed by a heat treatment without using plasma. However, from the viewpoint of preventing a decrease in throughput, plasma processing is preferable when forming a metal silicide film such as the TiSi film 14. Regarding the formation of the W films 16 and 17 in steps S3 and S4, these steps are not limited to non-plasma processing and may be performed by plasma processing. Furthermore, the W films 16 and 17 are not limited to being formed by CVD and may be formed by ALD.

Furthermore, although there has been described the example in which the TiSi film 14 is formed as the metal silicide film in step S1, the metal silicide film formed in step S1 is not limited to the TiSi film. For example, a ZrSi film may be formed using a plasma-converted ZrCl₄ gas. Therefore, the metal to be etched from the sidewall of the recess 13 in step S2 is the metal used to form this metal silicide, and step S2 is not limited to the process of etching Ti. The formation of the metal silicide nitride in step S2A is also the formation of the metal silicide nitride using the metal (first metal) used to form the metal silicide in step S1, and is not limited to the formation of the TiSiN film 21.

Although the W film 16 is formed on the metal silicide film by supplying the WCl₅ gas in step S3, the stacked metal film formed on the metal silicide film is not limited to the W film 16 and may be, for example, a Mo (molybdenum) film. When the Mo film is formed instead of the W film 16, step S3 may be performed by supplying a gas containing Mo, such as a MoCl₅(molybdenum pentachloride) gas, a MoO₂Cl₂ gas, or a MoOCl₄ gas, to the wafer A instead of the WCl₅ gas. Then, step S4 may be performed by supplying a gas, such as a MoF₆ (molybdenum hexafluoride) gas, to the wafer A to form a Mo film, and filling the recesses 13 with the Mo film.

Since MoCl₅has the same molecular structure as WCl₅, except that the constituent element thereof is Mo instead of W, supplying the MoCl₅gas to the wafer A will cause the same phenomenon as supplying the WCl₅ gas to the wafer A. That is, when the MoCl₅ gas is supplied to the wafer A in which the Ti film 15 has been formed on the sidewall of the recess 13, there may be a risk that a Mo film would be formed on the Ti film 15, which may cause problems in subsequent processing. However, even if the MoCl₅ gas is supplied to the SiN film 12 or the TiSiN film 21, the formation of a Mo film on the SiN film 12 or the TiSiN film 21 is suppressed.

Therefore, in supplying the MoCl₅ gas to the wafer A instead of the WCl₅ gas in step S3, the formation of the Mo film on the sidewall of the recess 13 is suppressed by performing steps S2 and S2A before step S3, thereby preventing defects in filling the recess 13 with the Mo film when step S4 is performed. Therefore, this technique is particularly effective when forming the Mo film in the recess 13 as well as when forming the W films 16 and 17 in the recess 13. The gases used to form the W film 16 or the W film 17 are not limited to those already mentioned. For example, a WCl₆ gas, a WOCl₄ gas, a WO₂Cl₂ gas, or the like may also be used.

The presently disclosed embodiments should be considered as being exemplary and not limitative in all respects, and the above-described embodiments may be omitted, substituted, modified, and/or combined in various ways without departing from the scope and spirit of the appended claims.

### Evaluation Test

The evaluation tests related to this technique will be described below. In these evaluation tests, the order of steps S2 and S2A in one cycle of the processing of the second embodiment differs from the order described in FIG. 4. Step S2A is performed first and step S2 is performed later.

### Evaluation Test 1

In Evaluation Test 1-1, steps S1, S3, and S4 were performed on the wafer A shown in FIG. 1, and SEM images of the processed wafer A were acquired to observe the condition of the bottom and side surfaces of the recesses 13. In Evaluation Test 1-2, the wafer A shown in FIG. 1 was processed in the same manner as Evaluation Test 1-1, except that step S2 was also performed on the wafer A, and SEM images were acquired to observe the condition of the bottom and side surfaces of the recesses 13. Therefore, in Evaluation Test 1-2, the wafer A was subjected to the processing of the first embodiment (i.e., steps S1 to S4). In Evaluation Test 1-3, the wafer A shown in FIG. 1 was processed in the same manner as Evaluation Test 1-1, except that steps S2 and S2A were also performed on the wafer A, and SEM images were acquired to observe the condition of the bottom and side surfaces of the recesses 13. Therefore, in Evaluation Test 1-3, the wafer A was subjected to the processing of the second embodiment.

In Evaluation Test 1-2, the etching time in step S2 (the time during which the wafer A is exposed to the plasma of the TiCl₄ gas and the Ar gas) was set to 300 seconds. In Evaluation Test 1-3, the execution time of one cycle (the sum of the execution time of step S2A performed once and the execution time of step S2 performed once) was set to 50 seconds. In addition, the number of times the cycle is executed was set to three. Therefore, steps S2A and S2 were executed alternately three times.

As a result of the observation, in Evaluation Test 1-1, the thickness of the W film 16 formed on the bottom portion of the recess 13 was 3.3 nm, and the thickness of the W film formed on the sidewall of the recess 13 was 2.6 nm. In Evaluation Test 1-2, the thickness of the W film 16 formed on the bottom portion of the recess 13 was 3.9 nm, and the thickness of the W film formed on the sidewall of the recess 13 was 1.2 nm. In Evaluation Test 1-3, the thickness of the W film 16 formed on the bottom portion of the recess 13 was 7.2 nm, and the thickness of the W film formed on the sidewall of the recess 13 was 1.6 nm. As described above, the ratio of the thickness of the W film 16 on the bottom portion of the recess 13 to the thickness of the W film on the sidewall of the recess 13 is in the order of Evaluation Tests 1-3 > 1-2 > 1-1. Therefore, in Evaluation Tests 1-2 and 1-3, the W film 16 was formed on the bottom portion of the recess 13, while the formation of the W film on the sidewall of the recess 13 being suppressed. This confirms the effectiveness of the technique of the present disclosure. Comparing the results of Evaluation Tests 1-2 and 1-3, it can be noted that the formation of the W film on the sidewall of the recess 13 is suppressed by the process of step S2A.

### Evaluation Test 2

In Evaluation Test 2-1, a plurality of substrates with flat Si films formed on their surfaces were prepared, and a Ti film was formed on each Si film by performing the same process on each substrate as in step S1. Then, each substrate was subjected to the same etching process as in step S2. That is, the Ti film was etched using plasma-converted TiCl₄ and Ar gases. This etching of the Ti film was performed with different etching times set for each substrate, and the amount of Ti film etched was measured using X-ray fluorescence analysis (XRF) after the etching. In Evaluation Test 2-2, the same test as in Evaluation Test 2-1 was performed, except that substrates with flat SiN films formed on their surfaces were used. Therefore, in Evaluation Test 2-2, the etching process was performed on a Ti film formed on a SiN film.

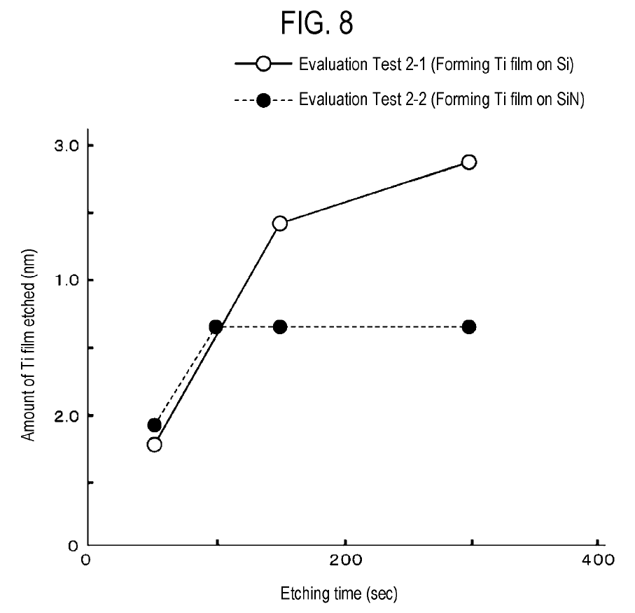

FIG. 8 is a graph showing the results of Evaluation Test 2. As shown in the graph, it was confirmed in both Evaluation Tests 2-1 and 2-2 that the Ti film can be etched by performing the process using the plasma-converted TiCl₄ and Ar gases. In Evaluation Test 2-1, the etching amount increases along with an increase in the etching time. However, in Evaluation Test 2-2 the etching amount increases along with an increase in the etching time within a range in which the etching time is relatively short, but remains constant within a range in which the etching time is relatively long. This is because the thickness of the Ti film formed on the SiN film was smaller than that on the Si film, and the Ti film was completely etched for the substrates for which the etching time is set relatively long in Evaluation Test 2-2. It can be confirmed from the results of Evaluation Test 2 that the Ti film 15 formed on the sidewall of the recess 13 formed by the SiN film 12 can be etched by performing step S2 described in the first and second embodiments.

### Evaluation Test 3

In Evaluation Test 3, a plurality of substrates with flat SiN films formed on their surfaces were prepared. A Ti film was formed on the SiN film using the same method as in step S1 of the embodiment. Thereafter, some of the substrates were processed using the same method as in step 2A of the embodiment. That is, the substrates were exposed to plasma of an H₂gas. The time of exposure to the plasma of the H₂gas was set differently for the respective substrates. Each substrate was then analyzed using X-ray photoelectron spectroscopy (XPS). In Evaluation Test 3, a test in which the substrates are not exposed to the plasma of the H₂ gas is referred to as Evaluation Test 3-1, and tests in which the processing times using the plasma of the H₂ gas are set to 90 seconds, 180 seconds, and 270 seconds, respectively, are referred to as Evaluation Tests 3-2, 3-3, and 3-4, respectively.

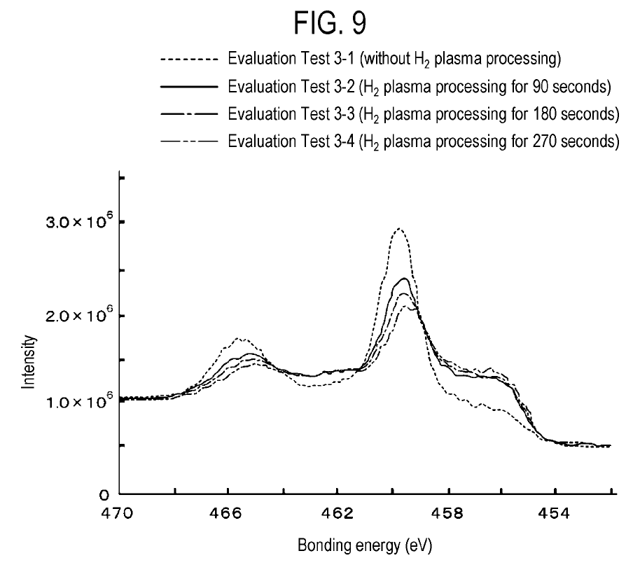

FIG. 9 is a graph showing the results of Evaluation Test 3, in which the horizontal axis means bonding energy (unit: eV) while the vertical axis means intensity (unitless). The spectral intensity at 460 to 459 eV indicates the amount of TiOₓ, and the intensity is in the order of Evaluation Tests 3-1 > 3-2 > 3-3 > 3-4. This TiOx was generated from Ti and TiSi when the substrate is exposed to the ambient air during XPS measurement. Therefore, the amounts of Ti and TiSi before XPS measurement are estimated to be in the order of Evaluation Tests 3-1 > 3-2 > 3-3 > 3-4. Furthermore, the spectral intensity at 456 eV indicates the amounts of TiN and TiSiN, and this intensity is greater in Evaluation Tests 3-2, 3-3, and 3-4 than in Evaluation Test 3-1. While there is little difference in intensity among Evaluation Tests 3-2, 3-3, and 3-4, Evaluation Test 3-4 has the greatest intensity, followed by Evaluation Test 3-3.

The results of Evaluation Test 3 show that the exposure of the substrate to the plasma of the H₂ gas causes Ti, which is an element constituting the Ti film, to be mixed with Si and N, which are elements constituting the SiN film. Therefore, it was confirmed that by performing the process of step S2A of the second embodiment, the TiSiN film 21 can be formed from the SiN constituting the sidewall of the recess 13 and the Ti film 15 on the sidewall.

### Evaluation Test 4

In Evaluation Test 4-1, a plurality of substrates with flat SiN films formed on their surfaces were prepared. A Ti film was formed on the SiN film using the same method as in step S1 of the embodiment. The Ti film was then etched using the same method as in step S2 of the embodiment, and a W film was then formed on the substrate using the same method as in step S3 of the embodiment. The W film formation time (the time for supplying the WCl₅gas to the substrate) was varied for each substrate. The thicknesses of the W film and the Ti film formed on each substrate were then measured using XRF. Evaluation Test 4-2 was also performed in the same manner as Evaluation Test 4-1, except that the Ti film was not etched.

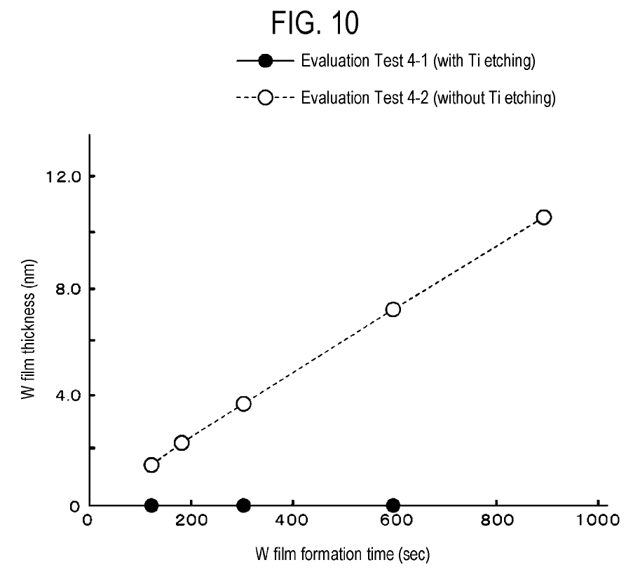

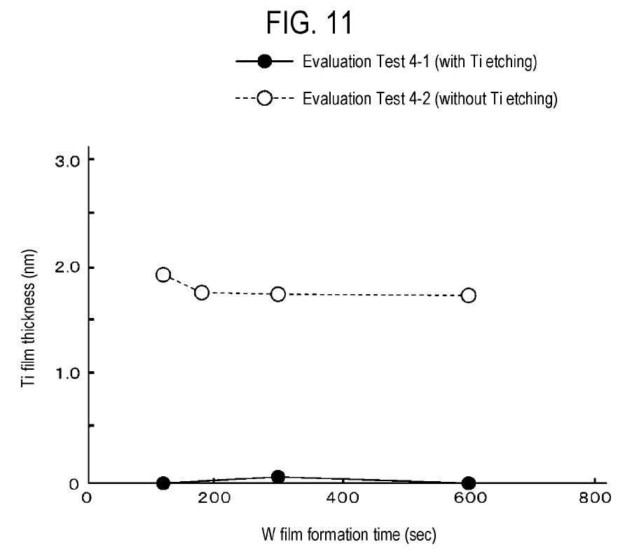

The graphs of FIGS. 10 and 11 show the results of Evaluation Test 4. In the graph of FIG. 10, the horizontal axis represents the W film formation time (unit: seconds), and the vertical axis represents the measured W film thickness (unit: nm). In the graph of FIG. 11, the horizontal axis represents the W film formation time (unit: seconds), and the vertical axis represents the measured Ti film thickness (unit: nm). From the graph of FIG. 11, it can be seen that for each substrate in Evaluation Test 4-2, a W film is formed on a Ti film, and then a W film is formed on the Ti film. Furthermore, from the graph of FIG. 10, it can be seen that in Evaluation Test 4-2, the thickness of the W film increases along with an increase in the film formation time. On the other hand, from the graph of FIG. 11, it can be seen that for each substrate in Evaluation Test 4-1, the W film formation process was performed with no or almost no Ti film formed on the substrate. Furthermore, from the graph of FIG. 10, it can be seen that in Evaluation Test 4-1, the W film thickness is zero regardless of the film formation time. That is, no W film was formed on each substrate in Evaluation Test 4-1.

The results of Evaluation Test 4 show that if the Ti film is formed on the SiN film, a W film is formed on the SiN film, whereas if the Ti film is not formed on the SiN film, a W film is not formed on the SiN film. Therefore, it was confirmed that etching the Ti film 15 on the sidewall of the recess 13 by performing step S2 described in the first and second embodiments is effective in preventing a W film from being formed on the sidewall of the recess 13 when step S3 is performed.

### Evaluation Test 5

In Evaluation Test 5-1, Ti films on the plurality of substrates each having a Ti film formed thereon were etched using the same method as in step S2 of the embodiment. In other words, in Evaluation Test 5-1, a TiCl₄ gas and an Ar gas were supplied to the substrates, and these gases were converted into plasma to etch the Ti film. The etching time (the time during which the substrate was exposed to the TiCl₄ gas and Ar gas plasma) was varied for each substrate. After etching, the amount of Ti film etched on each substrate was measured.

In Evaluation Test 5-2, a plurality of substrates each having a Ti film formed thereon were subjected to etching of the Ti film by the same method as in step S2B of the embodiment. That is, in Evaluation Test 5-2, a TiCl₄ gas and an Ar gas were supplied, and the Ti film was etched by heat treatment without converting these gases into plasma. The etching time (the time during which the TiCl₄ gas and the Ar gas are supplied to the substrate) was changed for each substrate. In Evaluation Test 5-2, the substrates were processed under the same processing conditions as in Evaluation Test 5-1, except that the gases were not converted into plasma and that the etching time for some substrates was different from the etching time for the substrates in Evaluation Test 5-1.

Furthermore, in Evaluation Test 5-3, only the Ar gas was supplied to a plurality of substrates each having a Ti film formed thereon, and the Ar gas was converted into plasma to etch the Ti film. In Evaluation Test 5-3, different etching times (times during which the substrates are exposed to the plasma of the Ar gas) were set for each substrate. In Evaluation Test 5-3, substrates were processed under the same processing conditions as in Evaluation Test 5-1, except that the Ar gas is not converted into plasma and that the etching times for some substrates are different from those for the substrates in Evaluation Test 5-1.

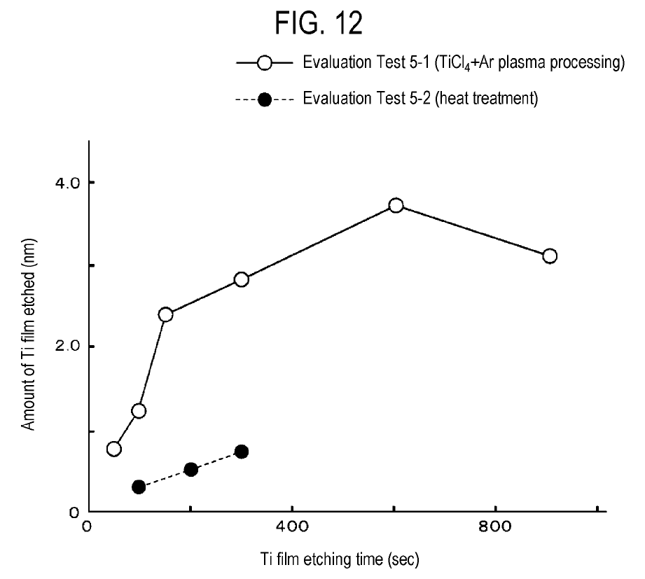

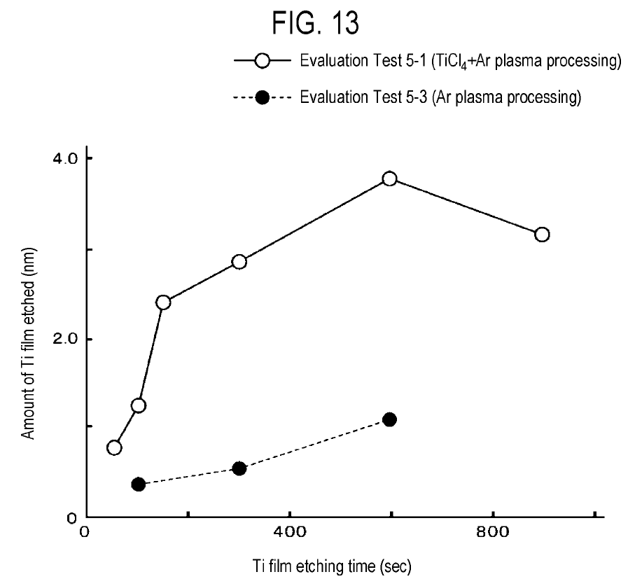

FIG. 12 is a graph showing the results of Evaluation Tests 5-1 and 5-2, and FIG. 13 is a graph showing the results of Evaluation Tests 5-2 and 5-3. In these graphs, the horizontal axis represents the etching time (unit: seconds) and the vertical axis represents the amount of Ti film etched (unit: nm). As shown in the graph of FIG. 12, the amount of Ti film etched in Evaluation Test 5-1 is greater than that in Evaluation Test 5-2 for each etching time. Therefore, it was confirmed that etching the Ti film 15 in the recess 13 by the plasma processing in step S2 as described in the embodiment can increase the throughput of the apparatus compared to etching the Ti film 15 without performing the plasma processing described in step S2B.

Furthermore, as shown in the graph of FIG. 13, the amount of Ti film etched is greater in Evaluation Test 5-1 than in Evaluation Test 5-3 at each etching time. Comparing the results of Evaluation Tests 5-2 and 5-3 from FIGS. 12 and 13, there is no significant difference in the amount of Ti film etched between Evaluation Tests 5-2 and 5-3 when the etching time is the same. These results show that the effect of plasma-converted TiCl₄ gas is significant in etching the Ti film. When the TiCl₄ gas is converted into plasma, unlike when the TiCl₄ gas is not converted into plasma, chlorine and activated chlorine species are generated as described in the embodiment. The generation of chlorine and activated chlorine species has also been confirmed by simulations.

Therefore, from the results of Evaluation Tests 5-1 to 5-3, it is estimated that chlorine and activated chlorine species contribute greatly to the etching of the Ti film. Simulations have confirmed that each of a chlorine gas and activated chlorine species reacts with Ti within the temperature range of 0 degrees C to 1,000 degrees C. As described above, Evaluation Test 5 shows that, when etching the Ti film 15 on the sidewall of the recess 13 according to the embodiment, performing the process by converting a metal chloride gas such as a TiCl₄ gas into plasma is effective in increasing the etching rate of the Ti film.

### Evaluation Test 6

In Evaluation Test 6-1, a Ti film was stacked on a substrate with a Si film formed thereon to form a TiSi film. The same process as in step S3 of the embodiment (i.e., supplying the WCl₅ gas) was performed, and the thickness of the W film formed on the TiSi film was measured. In Evaluation Test 6-2, a nitriding process was performed on the TiSi film formed in the same manner as in Evaluation Test 6-1 to form a TiSiN film. Then, the same process as in step S3 of the embodiment was performed, and the thickness of the W film formed on the TiSiN film was measured. In both Evaluation Tests 6-1 and 6-2, the W film formation time was changed for each substrate.

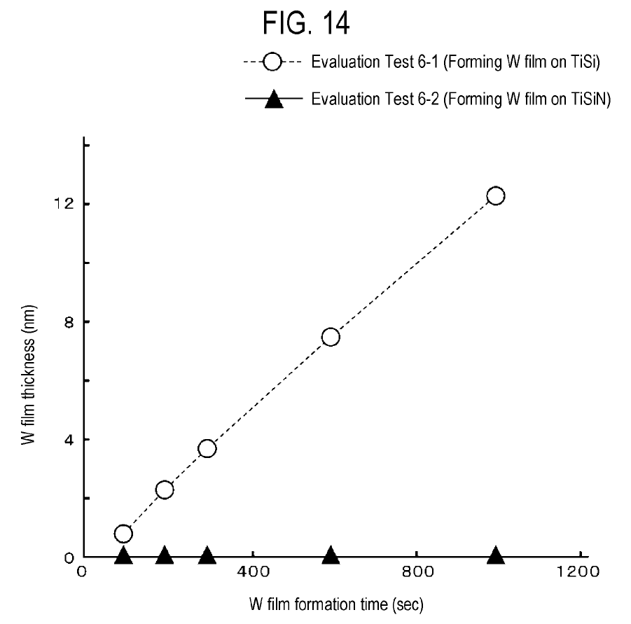

FIG. 14 is a graph showing the results of Evaluation Test 6, in which the horizontal axis represents the W film formation time (unit: seconds) and the vertical axis represents the W film thickness (unit: nm). As shown in this graph, in Evaluation Test 6-1, the W film thickness increases along with an increase in the film formation time. On the other hand, in Evaluation Test 6-2, the W film thickness was 0 nm regardless of the film formation time, i.e., no W film was formed. Therefore, the results of Evaluation Test 6 and the aforementioned Evaluation Test 3 indicate that by performing step S2A described in the embodiment and forming the TiSiN film 21 on the sidewall of the recess 13, it is possible to prevent the formation of a W film on the sidewall when the subsequent step S3 is performed.

The present disclosure can suppress film formation defects when forming a metal film to be used as a wiring on metal silicide in a recess of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method, comprising:
a process of supplying a first processing gas containing a first metal to a substrate having a recess in which a semiconductor layer containing silicon is exposed on a bottom surface of the recess and whose sidewall is formed by an insulator film, and forming a metal silicide film that forms a bottom wall of the recess;
a plasma processing process of performing at least one of a plasma etching process of supplying a plasma-converted etching gas to the substrate to remove a film of the first metal on the sidewall of the recess, or a sidewall processing process of supplying a plasma-converted second processing gas to the substrate to form a metal-containing film, which is a mixture of the first metal and elements constituting the insulator film, on the sidewall of the recess; and
a film formation process of supplying a first film-forming gas containing a second metal to the substrate after the plasma processing process and forming a stacked metal film stacked on the metal silicide film.

2. The method of claim 1, wherein the film formation process is stopped before the stacked metal film fills the recess, and wherein the method further comprises:
a process of supplying a second film-forming gas made of a compound different from the first film-forming gas to the substrate after the film formation process, and filling the recess with a metal film.

3. The method of claim 1, wherein the plasma processing process includes the plasma etching process, and the etching gas is a metal chloride gas.

4. The method of claim 3, wherein the first metal is titanium, the metal silicide film is a titanium silicide film, and the first processing gas and the etching gas contain titanium tetrachloride.

5. The method of claim 1, wherein the plasma processing process includes the sidewall processing process, the insulator film is a silicon nitride film, and the metal-containing film is a metal silicide nitride film.

6. The method of claim 5, wherein the second processing gas is a hydrogen gas.

7. The method of claim 5, further comprising:
an etching process of removing the film of the first metal on the sidewall of the recess by supplying a non-plasma-converted etching gas to the substrate after the forming the metal silicide film and before the forming the stacked metal film.

8. The method of claim 7, wherein the first metal is titanium, the metal silicide film is a titanium silicide film, and the first processing gas and the non-plasma-converted etching gas are a titanium tetrachloride gas.

9. The method of claim 1, wherein the plasma processing process includes the plasma etching process and the sidewall processing process.

10. The method of claim 9, wherein the plasma etching process is performed first, and the sidewall processing process is performed later.

11. The method of claim 9, wherein a cycle in which the plasma etching process and the sidewall processing process are alternately performed is repeated.

12. The method of claim 1, wherein the second metal is tungsten and the stacked metal film is a tungsten film, or the second metal is molybdenum and the stacked metal film is a molybdenum film.

13. A substrate processing apparatus, comprising:
a processing container configured to accommodate a substrate;
a first processing gas supply configured to supply a first processing gas containing a first metal into the processing container to the substrate having a recess in which a semiconductor layer containing silicon is exposed on a bottom surface of the recess and whose sidewall is formed by an insulator film, and form a metal silicide film that forms a bottom wall of the recess;
a plasma processing part including at least one of a plasma etching gas supply configured to supply a plasma-converted etching gas into the processing container to remove a film of the first metal on the sidewall of the recess, or a second processing gas supply configured to supply a plasma-converted second processing gas into the processing container to form a metal-containing film, which is a mixture of the first metal and an element constituting the insulator film, on the sidewall of the recess; and
a film-forming gas supply configured to supply a first film-forming gas containing a second metal into the processing container and form a stacked metal film stacked on the metal silicide film of the substrate processed by the plasma processing part.
